(19) United States
(12) Patent Application Publication
(10) Pub. No.: US 2007/0159796 A1
(43) Pub. Date: Jul. 12, 2007

(54) Heat sink with vertical air flow panels

(75) Inventors: Paul T. Artman, Austin, TX (US); William Coxe, Round Rock, TX (US); Robert Riegler, Austin, TX (US); Eric Tunks, Round Rock, TX (US)

Correspondence Address: Roger Fulghum;Baker Botts L.L.P., One Shell Plaza, 910 Louisiana Street, Houston, TX, 77002-4995, US

(73) Assignee: DELL PRODUCTS L.P.

(21) Appl. No.: 11/330,584

(22) Filed: Jan. 12, 2006

(51) Int. Cl. H05K 7/20

(52) U.S. Cl. 361/695

(57) ABSTRACT

A heat sink is disclosed that includes a set of horizontal fins that are coupled to multiple solid vertical panels. A fan is located near the heat sink to direct air across the surface of the horizontal fins. Vertical panels may be located on the opposite ends of the heat sink to prevent air from exiting from the heat sink in a direction that is perpendicular to the axis of the fan. The presence of the vertical panels within the interior of the heat sink is advantageous because the vertical panels direct the forced air from the fan so that the air flows through the fan in the direction of the axis of the fan.

### TECHNICAL FIELD

The present disclosure relates generally to computer systems and information handling systems, and, more particularly, to a heat sink that includes vertical air flow panels.

### BACKGROUND

As the value and use of information continues to increase, individuals and businesses seek additional ways to process and store information. One option available to these users is an information handling system. An information handling system generally processes, compiles, stores, and/or communicates information or data for business, personal, or other purposes thereby allowing users to take advantage of the value of the information. Because technology and information handling needs and requirements vary between different users or applications, information handling systems may vary with respect to the type of information handled; the methods for handling the information; the methods for processing, storing or communicating the information; the amount of information processed, stored, or communicated; and the speed and efficiency with which the information is processed, stored, or communicated. The variations in information handling systems allow for information handling systems to be general or configured for a specific user or specific use such as financial transaction processing, airline reservations, enterprise data storage, or global communications. In addition, information handling systems may include or comprise a variety of hardware and software components that may be configured to process, store, and communicate information and may include one or more computer systems, data storage systems, and networking systems.

A computer system may include one or more heat sinks. A heat sink is typically formed of a metal and is placed in the interior of the computer system to dissipate heat generated in the interior of the computer system. A heat sink may be placed in close proximity to a processor, for example, to absorb the heat generated by the processor and direct heat away from the processor. An active heat sink is characterized by the placement of a fan on or near the heat sink. The fan will directs air over the heat sink so that the heat being absorbed by the heat sink is dissipated into the interior or exterior of the computer system. Although a fan may be effective in directing air at a heat sink, the configuration of the fan itself may generate air swirl, which prevents air from being effectively passed through the heat sink. If the air flow generated by the fan generates air swirl and the air flow is not passed effectively through the heat sink, the ambient air temperature in the vicinity of the processor could rise, thereby compromising the operation of the processor and surrounding components.

### SUMMARY

In accordance with the present disclosure, a heat sink is disclosed that includes a set of horizontal fins that are coupled to multiple solid vertical panels. A fan is located near the heat sink to direct air across the surface of the horizontal fins. Vertical panels may be located on the opposite ends of the heat sink to prevent air from exiting from the heat sink in a direction that is perpendicular to the axis of the fan. The presence of the vertical panels within the interior of the heat sink is advantageous because the vertical panels direct the forced air from the fan so that the air flows through the heat sink in the direction of the axis of the fan. Because air is directed in the axial direction, swirl within the interior of the heat sink is minimized, allowing the heat sink to more efficiently dissipate heat within the interior of the heat sink. Other technical advantages will be apparent to those of ordinary skill in the art in view of the following specification, claims, and drawings.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 is a pictorial view of an active heat sink; and

FIG. 2 is a top cross-sectional view of an active heat sink that is bracketed on both sides by panels.

### DETAILED DESCRIPTION

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communication with external devices as well as various input and output (I/O) devices, such as a keyboard, a mouse, and a video display. The information handling system may also include one or more buses operable to transmit communications between the various hardware components.

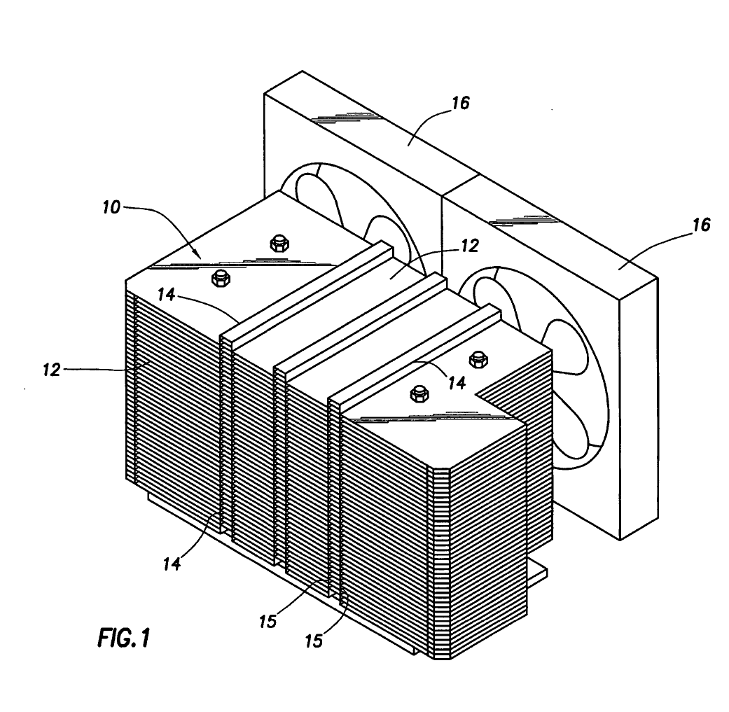

Shown in FIG. 1 is a pictorial view of a horizontally aligned, parallel plate heat sink 10. Heat sink 10 includes a number of horizontal fins 12. Horizontal fins 12 are generally planar and are arranged so that the horizontal fins are parallel to one another. In this configuration, the heat source for heat sink 10 will be located beneath the heat sink. The heat sink rests on top of the heat source and the heat from the heat source conducts upward and into the heat sink. One example of a heat source is the processor of the computer system. Also shown in FIG. 1 are a number of fans 16. Fans 16 direct air across the surface of the horizontal fins of the heat sink. The direction of the air flow is shown by the arrows of FIG. 1. The direction of the air flow is in an axial direction, which is defined as the direction of the axis of fan 16.

Heat sink 10 includes a number of vertical panels 14. Panels 14 are generally perpendicular to the horizontal fins of the heat sink and to the heat source, which is disposed beneath the heat sink. Panels 14 are preferably solid. In the example, of FIG. 1, each panel comprises two vertical fins 15 with a small space between the vertical fins. Alternatively, the each panel could comprise a single fin. The heat sink, including the fins is typically made of a metal with good heat conduction properties.

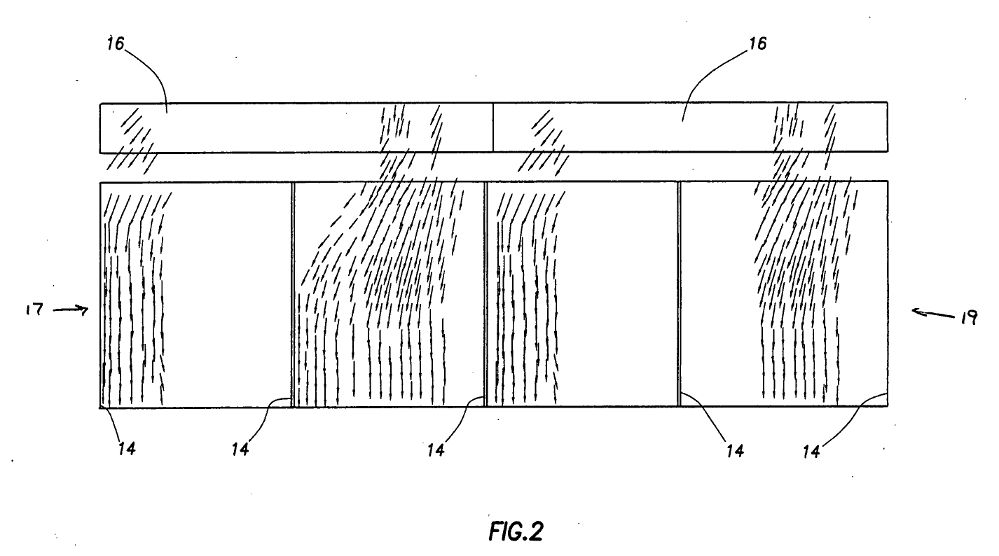

Shown in FIG. 2 is a top, cross-sectional view of the air flow patterns for the interior of heat sink 10. The heat sink 10 of FIG. 2 has a rectangular configuration. The arrows of FIG. 2 are an example of the direction of air flow through the interior of heat sink 10. Panels 14 cause the air flow to travel through the heat sink in predominantly axial direction. The forced air flow in a direction that is generally parallel to the plane of the panels 14. The air flow travels through the heat sink in the direction of the axis of the fan. Panels 14 prevent the air forced air from turning and flow in a direction that is perpendicular to the axis of the fan. Heat sink 10 includes two ends 17 and 19. A vertical panel 14 is placed at each end to bracket the heat sink on both of its sides and prevent air from exiting the heat sink in a direction that is perpendicular to the axis of the fan. Because the air cannot flow in a direction perpendicular to the axis of the fan, air swirl in the interior of the heat sink is minimized, if not eliminated entirely. Instead, the air flow from the fan is in the axial direction of the fan and across the heat sink.

Although it is shown in the figures herein that the fan is shown as forcing air across the heat sink in a first axial direction, it should be recognized that the fan could direct air across the heat sink in the opposite axial direction. Although the present disclosure has been described in detail, it should be understood that various changes, substitutions, and alterations can be made hereto without departing from the spirit and the scope of the invention as defined by the appended claims.

What is claimed is:

1. A heat sink, comprising:
a plurality of horizontal fins;
a plurality of vertical panels, wherein the panels are solid and the horizontal fins are coupled to the vertical panels, and wherein the fins form a barrier to direct air in a direction that is generally parallel to the surface of the vertical panels.

2. The heat sink of claim 1, wherein the heat sink is formed of a metal.

3. The heat sink of claim 1, wherein the heat sink is enclosed on opposite sides by vertical panels.

4. The heat sink of claim 1, wherein each vertical panel comprises multiple, parallel vertical fins.

5. The heat sink of claim 4, wherein an air gap is formed between the parallel vertical fins.

6. The heat sink of claim 1,
wherein the heat sink is enclosed on opposite sides by vertical panels; and
wherein the at least one additional vertical panel is included within the heat sink and between the vertical panels that enclose the heat sink on opposite ends.

7. The heat sink of claim 1,
wherein each vertical panel comprises multiple, parallel vertical fins;
wherein the heat sink is enclosed on opposite sides by vertical panels; and
wherein the at least one additional vertical panel is included within the heat sink and between the vertical panels that enclose the heat sink on opposite ends.

8. An active heat sink, comprising:
a fan;
a heat sink position proximate the fan, wherein the heat sink comprises,
a plurality of horizontal fins;
a plurality of vertical panels, wherein the panels are solid and the horizontal fins are coupled to the vertical panels, and wherein the fins form a barrier to direct air from the fan in a direction that is generally parallel to the surface of the vertical panels.

9. The active heat sink of claim 8, the heat sink is formed of a metal.

10. The active heat sink of claim 8, wherein the heat sink is enclosed on opposite sides by vertical panels.

11. The active heat sink of claim 8, wherein each vertical panel comprises multiple, parallel vertical fins.

12. The active heat sink of claim 11, wherein an air gap is formed between the parallel vertical fins.

13. The active heat sink of claim 1,
wherein the heat sink is enclosed on opposite sides by vertical panels; and
wherein the at least one additional vertical panel is included within the heat sink and between the vertical panels that enclose the heat sink on opposite ends.

14. The active heat sink of claim 1,
wherein each vertical panel comprises multiple, parallel vertical fins;
wherein the heat sink is enclosed on opposite sides by vertical panels; and
wherein the at least one additional vertical panel is included within the heat sink and between the vertical panels that enclose the heat sink on opposite ends.

15. An information handling system, comprising:
a processor;
memory;
an active heat sink for dissipating heat produced a heat source within the interior of the computer system, the active heat sink comprises,
a fan;
a heat sink proximate the fan, wherein the heat sink comprises,
a plurality of horizontal fins;
a plurality of vertical panels, wherein the panels are solid and the horizontal fins are coupled to the vertical panels, and wherein the fins form a barrier to direct air from the fan in a direction that is generally parallel to the surface of the vertical panels.

16. The information handling system of claim 15, wherein the heat sink is enclosed on opposite sides by vertical panels.

17. The information handling system of claim 15, wherein each vertical panel comprises multiple, parallel vertical fins.

18. The information handling system of claim 17, wherein an air gap is formed between the parallel vertical fins.

19. The information handling system of claim 15,
wherein the heat sink is enclosed on opposite sides by vertical panels; and
wherein the at least one additional vertical panel is included within the heat sink and between the vertical panels that enclose the heat sink on opposite ends.

20. The information handling system of claim 15,
wherein each vertical panel comprises multiple, parallel vertical fins;
wherein the heat sink is enclosed on opposite sides by vertical panels; and
wherein the at least one additional vertical panel is included within the heat sink and between the vertical panels that enclose the heat sink on opposite ends.
